(19) United States
(12) Patent Application Publication
(10) Pub. No.: US 2026/0245837 A1
(43) Pub. Date: Aug. 20, 2026

(54) ARC-RESISTANT ELECTROSTATIC CHUCKS AND ARC-REDUCING PLUGS FOR ELECTROSTATIC CHUCKS

(71) Applicant: LAM RESEARCH CORPORATION, Fremont, CA (US)

(72) Inventors: Alexander MATYUSHKIN, San Jose, CA (US); Keith COMENDANT, Fremont, CA (US); Eric SAMULON, Oaklnad, CA (US); Darell EHRLICH, San Jose, CA (US)

(21) Appl. No.: 19/159,523

(22) PCT Filed: Feb. 28, 2024
(86) PCT No.: PCT/US2024/017596

§ 371 Date: Aug. 25, 2025

Related U.S. Application Data
(60) Provisional application No. 63/449,983, filed on Mar. 4, 2023.

(51) Int. Cl. H01J 37/32; H10P 72/72

(52) U.S. Cl. CPC H01J 37/32724; H01J 37/32449; H01J 37/32697; H10P 72/722

(57) ABSTRACT

An arc-resistant electrostatic chuck includes a baseplate including a first gas supply hole to supply a heat transfer gas through the baseplate and a first cavity arranged on a first surface of the baseplate and in fluid communication with the first gas supply hole. A top ceramic layer is arranged above the baseplate and including a second cavity on a first surface thereof. A bonding layer is configured to bond the baseplate to the top ceramic layer and including a relief area. A first plug is arranged in the first cavity of the baseplate. The top ceramic layer includes N gas supply holes arranged above the first plug and including outlets located in the second cavity, where N is an integer greater than 20. Inlets of the N gas supply holes are located in the relief area.

### CROSS-REFERENCE TO RELATED APPLICATIONS

This application claims the benefit of U.S. Provisional Application No. 63/449,983, filed on Mar. 4, 2023. The entire disclosure of the application referenced above is incorporated herein by reference.

### FIELD

The present disclosure relates to substrate processing systems, and more particularly to an arc-resistant electrostatic chuck.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems perform treatments on substrates such as semiconductor wafers. Examples of substrate treatments include deposition, ashing, etching, cleaning and/or other processes. During processing, a substrate is arranged in the processing chamber on a substrate support such as an electrostatic chuck (ESC). A gas delivery system supplies a gas or vapor mixture to the processing chamber to treat the substrate. Plasma may be used to ignite the gas mixture in the processing chamber to enhance chemical reactions.

### SUMMARY

An arc-resistant electrostatic chuck includes a baseplate including a first gas supply hole to supply a heat transfer gas through the baseplate and a first cavity arranged on a first surface of the baseplate and in fluid communication with the first gas supply hole. A top ceramic layer is arranged above the baseplate and includes a second cavity on a first surface thereof. A bonding layer is configured to bond the baseplate to the top ceramic layer and includes a relief area. A first plug is arranged in the first cavity of the baseplate. The top ceramic layer includes N gas supply holes arranged above the first plug and including outlets located in the second cavity, where N is an integer greater than 20. Inlets of the N gas supply holes are located in the relief area.

In other features, N is in a range from 300 to 1200. The N gas supply holes have a diameter in a range from 3 μm to 30 μm. The N gas supply holes are laser drilled. The first plug comprises a porous plug. The porous plug is in a range from 30% to 50% porous and includes open pores.

In other features, the first plug comprises a multi-lumen plug including a P gas supply holes that are oriented at a predetermined angle relative to a vertical direction, where P is an integer greater than 20. The predetermined angle is in a range between 0.5° and 5°. P is in a range from greater than 100 to less than 1000. A first multi-lumen plug includes M gas supply holes and is arranged in a third cavity on a second surface of the top ceramic layer adjacent to the bonding layer, wherein M is an integer greater than 20.

In other features, M is greater than 100. A diameter of the M gas supply holes is in a range from 3 μm to 10 μm.

In other features, the first multi-lumen plug further includes a solid core. The M gas supply holes of the first multi-lumen plug pass vertically through the first plug radially outside of the solid core. The solid core has an outer diameter that is greater than a diameter within which the N gas supply holes are located. The first plug comprises a porous plug. The porous plug is in a range from 30% to 50% porous and includes open pores. The first plug comprises a second multi-lumen plug including a plurality of gas supply holes that are oriented at a predetermined angle relative to a vertical direction. The predetermined angle is in a range between 0.5° and 5°. The first plug comprises a second multi-lumen plug including T gas supply holes extending vertically through the second multi-lumen plug, where T is an integer greater than 20. The second multi-lumen plug further comprises a solid core. The T gas supply holes are arranged radially outside of the solid core.

In other features, the first plug comprises a solid plug including a gas supply hole extending vertically through the solid plug. The gas supply hole has a diameter in a range from 100 μm to 500 μm. The solid plug includes a body with a “T”-shaped cross-section and a flange extending outwardly from an upper surface of the body.

In other features, the second cavity in the top ceramic layer includes a raised portion and an annular plenum surrounding the raised portion. Outlets of the N gas supply holes are arranged on the raised portion. The solid plug includes a “T”-shaped body including an annular gas channel extending from a bottom surface into the “T”-shaped body and P gas supply holes extending from the annular gas channel to a top surface of the “T”-shaped body, where P is greater than 10.

In other features, the first plug includes a first plug portion having a “T” shaped outer cross-section, a cavity extending from a first surface, and a second plug portion having a “T”-shaped body that is inverted and inserted into the cavity. The second plug portion includes a gas supply hole extending vertically through the second plug portion, and the first plug portion includes P gas supply holes extending from the cavity to a top surface of the first plug portion, where P is an integer greater than 10. The P gas supply holes have a diameter in a range from 20 μm to 150 μm. The P gas supply holes are arranged in a circular pattern and P is less than 500.

In other features, a plenum is defined between an upper surface of the second plug portion and the cavity of the first plug portion. A bottom portion of the first multi-lumen plug extends vertically into the relief area. The first plug includes a body having a “T”-shaped cross section, a plenum extending horizontally in the body, and a gas channel extending from a bottom surface of the body to a location spaced from the plenum. P gas supply holes fluidly connect the gas channel to the plenum. Q gas supply holes fluidly connecting the plenum to a top surface of the body, wherein P and Q are integers greater than one.

In other features, the Q gas supply holes comprise 32 to 150 holes having a diameter in a range from 30 μm to 80 μm. The P gas supply holes comprise 1 to 20 holes and have a diameter in a range from 100 μm to 200 μm. A lower portion of the first plug tapers inwardly away from the first cavity in the baseplate.

An arc-resistant electrostatic chuck includes a baseplate including a first gas supply hole to supply a heat transfer gas and a first cavity arranged on a surface of the baseplate and in fluid communication with the first gas supply hole. A top ceramic layer is arranged above the baseplate and includes a second cavity arranged on a first side of the top ceramic layer, an annular projection extending into the first cavity and defining a gas supply hole, a plenum arranged below the annular projection, and a third cavity arranged below the plenum. A bonding layer is configured to bond the baseplate to the top ceramic layer and includes a relief area adjacent to the first cavity. A first plug is arranged in the first cavity of the baseplate. A first multi-lumen plug is arranged in the third cavity in the top ceramic layer and including N gas supply holes, wherein N is greater than 20.

In other features, N is in a range from 100 to 900. The N gas supply holes have a diameter in a range from 3 μm to 10 μm. The N gas supply holes are laser drilled. The first plug comprises a porous plug. The porous plug is in a range from 30% to 50% porous and includes open pores. The first plug comprises a second multi-lumen plug including P gas supply holes, where P is an integer greater than 20. The second multi-lumen plug includes a solid core and the P gas supply holes are arranged radially outside of the solid core. P is an integer in a range from 100 to less than 1000. A diameter of the P gas supply holes is in a range from 3 μm to 10 μm. The P gas supply holes of the second multi-lumen plug are oriented at a predetermined angle relative to a vertical direction. The predetermined angle is in a range between 0.5° and 5°.

In other features, the first multi-lumen plug includes a solid core. The N gas supply holes are located radially outside of the solid core. The solid core has an outer diameter that is greater than a first diameter of the gas supply hole. The first multi-lumen plug includes a solid core and wherein the second multi-lumen plug includes a solid core. The first plug comprises a solid plug including a gas supply hole extending vertically through the solid plug. The solid plug has a “T”-shaped cross-section and includes a flange extending outwardly from a body of the solid plug.

In other features, the first plug includes a “T”-shaped body including an annular gas channel extending from a bottom surface into the “T”-shaped body. Gas supply holes extend from the annular gas channel to a top surface of the “T”-shaped body.

In other features, the first plug includes a first plug portion including a “T” shaped outer cross-section and a cavity extending into the first plug portion. A second plug portion has a “T”-shaped body that is inserted into the cavity of the first plug portion. The second plug portion includes one or more gas supply holes extending vertically through the second plug portion. The first plug portion includes one or more gas supply holes extending from the cavity to a top surface of the first plug portion.

In other features, a bottom portion of the first multi-lumen plug extends into the relief area. The first plug includes a body, a plenum extending horizontally in the body, a gas channel extending from a bottom surface of the body to a location spaced from the plenum, P gas supply holes fluidly connecting the gas channel to the plenum, and Q gas supply holes fluidly connecting the plenum to a top surface of the body, wherein P and Q are integers greater than one.

In other features, the Q gas supply holes are located radially outside of a radially outer edge of the first multi-lumen plug. The Q gas supply holes comprise 32 to 150 holes having a diameter in a range from 30 μm to 80 μm. The P gas supply holes comprise 1 to 20 holes having a diameter in a range from 100 μm to 200 μm. A lower portion of the first plug tapers radially inwardly away from the first cavity in the baseplate.

An arc-resistant electrostatic chuck includes a baseplate including a first gas supply hole to supply a heat transfer gas. A first cavity is arranged on a surface of the baseplate and in fluid communication with the first gas supply hole. A top ceramic layer is arranged above the baseplate and includes a second cavity arranged on a first side of the top ceramic layer. A gas supply hole fluidly connects the second cavity to a bottom surface of the top ceramic layer. A bonding layer is configured to bond the baseplate to the top ceramic layer and includes a relief area located adjacent to the first cavity. A multi-lumen plug is arranged in the first cavity and includes a solid core and T gas supply holes arranged around the solid core, wherein T is greater than 20.

In other features, T is an integer in a range from 100 to less than 1000. A diameter of the T gas supply holes is in a range from 3 μm to 10 μm.

An arc-resistant electrostatic chuck includes a baseplate including a first gas supply hole to supply a heat transfer gas. A first cavity is arranged on a surface of the baseplate and in fluid communication with the first gas supply hole. A top ceramic layer is arranged above the baseplate and includes a second cavity arranged on a first side of the top ceramic layer. A gas supply hole fluidly connects the second cavity to a second surface of the top ceramic layer. A bonding layer is configured to bond the baseplate to the top ceramic layer and includes a relief area adjacent to the first cavity. A plug is arranged in the first cavity and includes a body, a plenum extending horizontally in the body, a gas channel extending from a bottom surface of the body to a location spaced from the plenum, P gas supply holes fluidly connecting the gas channel to the plenum, and Q gas supply holes fluidly connecting the plenum to a top surface of the body, wherein P and Q are integers greater than one.

In other features, the Q gas supply holes are located radially outside of the P gas supply holes. The Q gas supply holes comprise 32 to 150 holes having a diameter in a range from 30 μm to 80 μm. The P gas supply holes comprise 1 to 20 holes and have a diameter in a range from 100 μm to 200 μm. A lower portion of the first plug tapers inwardly away from the first cavity in the baseplate.

An arc-resistant electrostatic chuck includes a baseplate including a first gas supply hole to supply a heat transfer gas and a first cavity arranged on a surface of the baseplate and in fluid communication with the first gas supply hole. A top ceramic layer is arranged above the baseplate and includes a second cavity arranged on a first side of the top ceramic layer. A gas supply hole fluidly connects the second cavity to a bottom surface of the top ceramic layer. A bonding layer is configured to bond the baseplate to the top ceramic layer and including a relief area adjacent to the first cavity. A first plug including a “T”-shaped body includes an annular gas channel extending from a bottom surface into the “T”-shaped body and P gas supply holes extending from the annular gas channel to a top surface of the “T”-shaped body, where P is an integer greater than 10.

In other features, P is an integer in a range from 10 to less than 1000. The P gas supply holes have a diameter in a range from 30 μm to 150 μm.

An arc-resistant electrostatic chuck includes a baseplate including a first gas supply hole to supply a heat transfer gas and a first cavity arranged in a surface of the baseplate in fluid communication with the first gas supply hole. A top ceramic layer is arranged above the baseplate and includes a second cavity arranged on a first side of the top ceramic layer. A gas supply hole fluidly connects the second cavity to a bottom surface of the top ceramic layer. A bonding layer is configured to bond the baseplate to the top ceramic layer and including a relief area adjacent to the first cavity. A first plug includes a first plug portion having a “T” shaped outer cross-section and a cavity extending upwardly from a bottom surface of the first plug portion. A second plug portion has a “T”-shaped body that is inserted into the cavity of the first plug portion. The second plug portion includes one or more gas supply holes extending vertically through the second plug portion. The first plug portion includes P gas supply holes extending from the cavity to a top surface of the first plug portion, where P is an integer greater than 10.

In other features, P is an integer in a range from 10 to less than 1000. The P gas supply holes have a diameter in a range from 30 μm to 150 μm. The first plug portion and the second plug portion are made of ceramic.

An arc-reducing plug for a heat transfer gas hole in a baseplate of an electrostatic chuck includes a body having a “T”-shaped cross-section including a flange. An annular gas channel extends from a first surface of the body distal from the flange. P gas supply holes extend from the annular gas channel to a second surface of the body adjacent to the flange. P is an integer in a range from 10 to less than 1000. The P gas supply holes have a diameter in a range from 30 μm to 150 μm. The body is made of ceramic.

An arc-reducing plug for a heat transfer gas hole in a baseplate of an electrostatic chuck includes a first plug portion having a “T” shaped outer cross-section and a cavity extending upwardly from a first surface of the first plug portion. A second plug portion has a “T”-shaped cross-section that is inverted and inserted into the cavity of the first plug portion. The second plug portion includes one or more gas supply holes extending vertically through the second plug portion. The first plug portion includes P gas supply holes extending from the cavity to a top surface of the first plug portion. P is an integer in a range from 10 to less than 1000.

In other features, the P gas supply holes have a diameter in a range from 30 μm to 150 μm. The first plug portion and the second plug portion are made of ceramic.

An arc-reducing plug for a heat transfer gas hole of an electrostatic chuck includes a body and a plenum extending horizontally in the body. A gas channel extends from a bottom surface of the body to a location spaced from the plenum. P gas supply holes fluidly connect the gas channel to the plenum. Q gas supply holes fluidly connect the plenum to a top surface of the body, wherein P and Q are integers greater than one.

In other features, the Q gas supply holes are located radially outside of the P gas supply holes. The Q gas supply holes comprise 32 to 150 holes having a diameter in a range from 30 μm to 80 μm. The P gas supply holes comprise 1 to 20 holes and have a diameter in a range from 100 μm to 200 μm. A lower portion of the first plug tapers inwardly.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system including an arc-resistant electrostatic chuck (ESC) according to the present disclosure;

FIG. 2 is a partial side cross-sectional view illustrating an example of the arc-resistant ESC according to the present disclosure;

FIGS. 3 to 9A are partial side cross-sectional views illustrating additional examples of the arc-resistant ESC according to the present disclosure;

FIGS. 9B and 9C are partial side cross-sectional views illustrating examples of the top ceramic layer according to the present disclosure;

FIGS. 10 and 11 are partial side cross-sectional views illustrating additional examples of the arc-resistant ESC according to the present disclosure;

FIGS. 12 to 14 are partial side cross-sectional views illustrating examples of plugs according to the present disclosure; and

FIGS. 15 and 16 are partial side cross-sectional views illustrating additional examples of the arc-resistant ESC according to the present disclosure.

In the drawings, reference numbers may be reused to identify similar and/or identical elements.

### DETAILED DESCRIPTION

An ESC includes a baseplate, a top ceramic layer, and a bonding layer attaching the top ceramic layer to the baseplate. The baseplate may include heat cooling passages to receive cooling fluid to control a temperature of the ESC and substrate during processing. The top ceramic layer or plate may include resistive heaters to control the temperature of the substrate.

A heat transfer gas such as helium (He) may be supplied to a back side of the substrate via a plurality of gas supply holes in the ESC to cool the substrate. For low-voltage applications, a single straight vertical hole in the top ceramic layer and a ceramic sleeve arranged the baseplate are used to prevent direct line of sight between the plasma and exposed metal surfaces to reduce arcing risk. For mid-low voltage applications, the ceramic sleeve is replaced by a porous plug to provide a higher withstand voltage threshold as compared to using the ceramic sleeves. For mid-voltage applications, the porous plugs are also arranged in the top ceramic layer in addition to the ceramic sleeves in the baseplate to reduce arcing.

While these solutions are adequate for low-and medium-voltage applications (e.g., <<10 kW), some semiconductor manufacturing processes generate plasma using very high RF power (e.g., >10 KW). The increase in RF power causes a corresponding increase in RF current and total voltage applied to the ESC. Some plasma etch processes may require significantly lower RF frequencies (e.g., 2 MHz, 400 kHz, or lower) than the frequencies that were used previously (e.g., 13.6 MHz). Low RF frequencies cause an additional increase in RF voltage applied across the top ceramic layer of the ESC.

High RF voltage applied across the top ceramic layer of the ESC may cause electrical discharge or arcing between the substrate and baseplate and/or ignition of heat transfer gas such as He in the gas supply holes. Arcing of the ESC usually causes catastrophic destruction of the chamber component and the substrate and may cause damage to other chamber components. In addition, the manufacturing process needs to be interrupted when arcing occurs.

When light-up of the heat transfer gas occurs, ESC destruction can be either a catastrophic event or slowly developing damage. Slowly developing damage affects multiple substrates that are processed and component damage is typically not detectable until much later. In both cases, ESC failure causes significant loss in substrate production.

The present disclosure relates to arc-resistant ESCs that reduce arcing and/or light-up of heat transfer gas in substrate processing systems using plasma at high RF power levels (>>10 KW (e.g., >50 kW)). In some examples, the arc-resistant ESC includes various combinations of features such as a top ceramic layer including a plurality of gas holes arranged over a heat transfer gas hole in the baseplate, a porous plug, a micro-lumen plug, a micro-lumen plug with a solid core, a slanted micro-lumen plug, a solid sleeve, a solid sleeve with an internal plenum, and/or one or more other structures that reduce arcing and light-up of heat transfer gas.

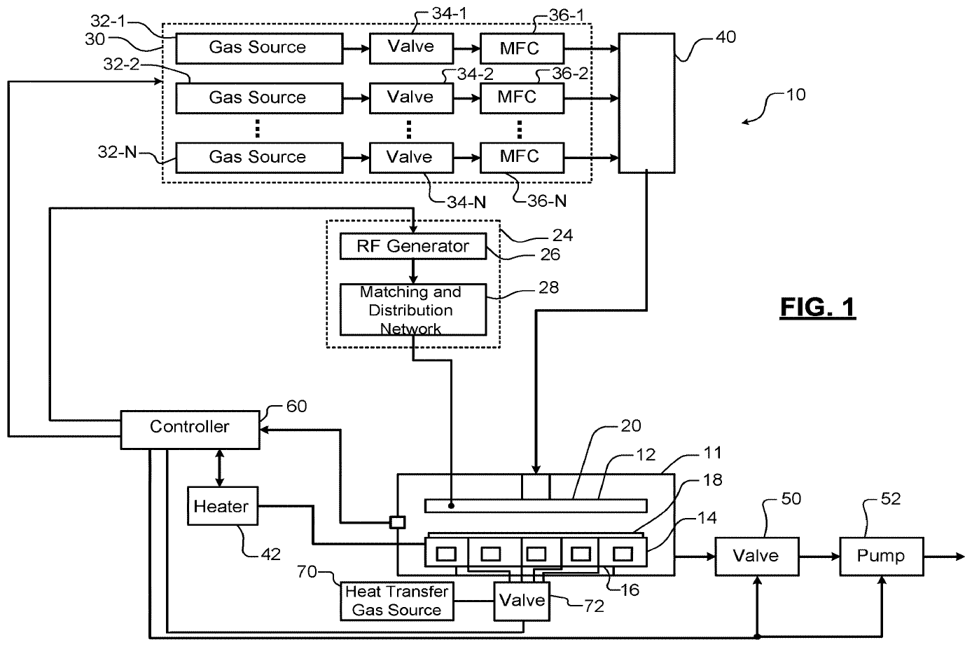

Referring now to FIG. 1, an example of a substrate processing system 10 including an arc-resistant ESC is shown. In the example set forth below, the substrate processing system 10 performs etching using capacitively-coupled plasma (CCP). While CCP is shown, the arc-resistant ESC can be used in other plasma-based processes. For example, the plasma may be generated using inductively coupled plasma (ICP), microwave plasma, remote plasma, etc.

The substrate processing system 10 includes a processing chamber 11 that encloses other components of the substrate processing system 10 and contains the RF plasma. The substrate processing system 10 includes an upper electrode 12 and an arc-resistant ESC 14 including a lower electrode 16. A substrate 18 is arranged on the arc-resistant ESC 14 between the upper electrode 12 and the lower electrode 16.

For example only, the upper electrode 12 may include a showerhead 20 that introduces and distributes process gases. Alternately, the upper electrode 104 may include a conducting plate and the process gases may be introduced using an injector or another device. The baseplate of the ESC 14 acts as the lower electrode 16.

An RF generating system 24 generates and outputs an RF voltage to one of the upper electrode and the lower electrode. The other one of the upper electrode and the lower electrode may be DC grounded, AC grounded or floating. For example only, the RF generating system 24 may include an RF voltage generator 26 that generates the RF voltage that is fed by a matching and distribution network 28 to the upper electrode 12 or the lower electrode 16.

An example of a gas delivery system 30 is shown in FIG. 1. A gas delivery system 30 includes one or more gas sources 32-1, 32-2, . . . , and 32-N (collectively gas sources 32), where N is an integer greater than zero. The gas sources supply one or more gas mixtures, inert gases, purge gases, etc. The gas sources 32 are connected by valves 34-1, 34-2, . . . , and 34-N (collectively valves 34) and mass flow controllers 36-1, 36-2, . . . , and 36-N (collectively mass flow controllers 36) to a manifold 40. An output of the manifold 40 is fed to the processing chamber 11. For example only, the output of the manifold 40 is fed to the showerhead 20.

A heater 42 may be connected to a heater coil (not shown) arranged in the arc-resistant ESC 14 to heat the arc-resistant ESC 14. The heater 42 may be used to control a temperature of the arc-resistant ESC 14 and the substrate 18. A valve 50 and pump 52 may be used to evacuate reactants from the processing chamber 11. A controller 60 may be used to control various components of the substrate processing system 10. For example only, the controller 60 may be used to control flow of process, carrier and precursor gases, striking and extinguishing plasma, removal of reactants, monitoring of chamber parameters, etc. A heat transfer gas source 70 and valve 72 are configured to provide heat transfer gas through the arc-resistant ESC 14 to a back side of the substrate 18 as will be described further below.

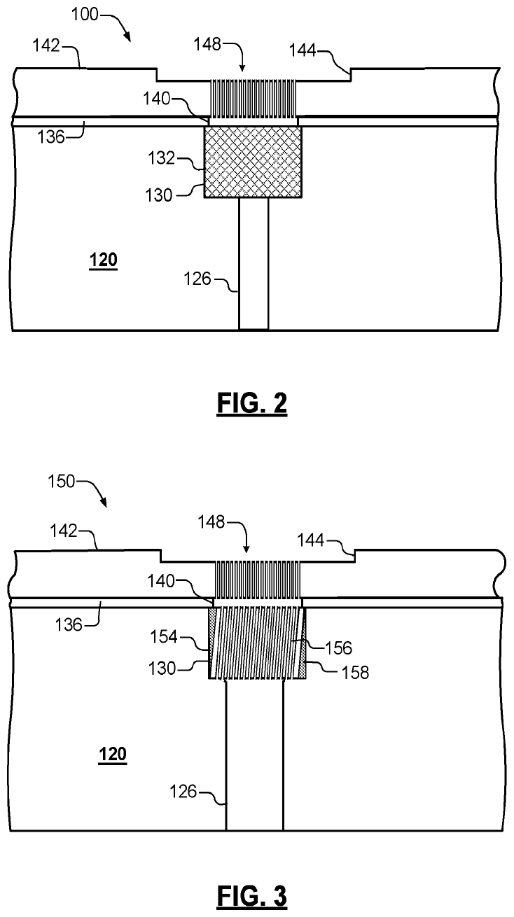

Referring now to FIG. 2, an arc-resistant ESC 100 according to the present disclosure includes a baseplate 120 with a plurality of vertical gas supply holes 126 for delivering a heat transfer gas to a back side of the substrate. For purposes of clarity, the following description will describe various components for reducing arcing and light up of the heat transfer gas for one vertical gas supply hole 126.

The baseplate 120 includes a cavity 130 arranged adjacent to an upper surface of the baseplate 120. The vertical gas supply hole 126 extends from a bottom surface of the baseplate 120 to the cavity 130. A porous plug 132 is arranged in the cavity 130. In some examples, the porous plug 132 is made of ceramic (e.g., alumina). In some examples, the porous plug 132 is in a range from 30% to 50% porous and has open pores. In some examples, the cavity 130 and the porous plug 132 have a cylindrical shape.

A bond layer 136 is arranged on the top surface of the baseplate 120 to bond a top ceramic layer 142 to the baseplate 120. In some examples, the top ceramic layer 142 has a thickness in a range from 0.5 mm to 1.5 mm. In some examples, the bond layer 136 has a thickness in a range from 0.1 mm to 1 mm. The bond layer 136 includes a relief area 140 for the heat transfer gas to pass through the bond layer 136. The relief area 140 defines a plenum between the top ceramic layer 142 and the top surface of the baseplate 120.

The top ceramic layer 142 includes a cavity 144 arranged on a top surface thereof. The cavity 144 is arranged above the vertical gas supply hole 126. N gas supply holes 148 extend vertically through the top ceramic layer 142 above the porous plug 132. In some examples, N is greater than 20. In some examples, N is in a range from 300 to 1200. In some examples, the N gas supply holes 148 are drilled using a laser or other drilling device. In some examples, the N gas supply holes 148 have a first diameter in a range from 3 μm to 30 μm. In some examples, the top ceramic layer 142 has a thickness in a range from 0.5 mm to 1 mm. In some examples, the N gas supply holes 148 are parallel to one another and parallel to an axial direction.

In some examples, the N gas supply holes 148 are located within a second diameter that is less than a third diameter of the porous plug 132 and/or a fourth diameter of the relief area 140. In some examples, the third diameter of the porous plug 132 is greater than the fourth diameter of the relief area 140.

Referring now to FIG. 3, another example of an arc-resistant ESC 150 that is similar to the arc-resistant ESC 100 is shown. A slanted multi-lumen plug 154 is used instead of the porous plug 132 of FIG. 2. In some examples, the slanted multi-lumen plug 154 includes gas supply holes 156 that are parallel to one another but offset from vertical by a predetermined angle. In some examples, the predetermined angle is determined based on a diameter of the gas supply holes 156 and the vertical height of the slanted multi-lumen plug 154 and is selected to prevent direct line of sight. In some examples, the predetermined angle is in a range from 0.5° to 10° (e.g., 0.5° to 5°). In some examples, the diameter of the gas supply holes 156 is in a range from 3 μm to 40 μm. The slanted holes in the slanted multi-lumen plug 154 prevent direct line of sight though the multi-lumen plug 210 to the baseplate 120.

In some examples, the slanted multi-lumen plug 154 is initially made with the gas supply holes 156 extending vertically. The slanted multi-lumen plug 154 is cut at the predetermined angle relative to a transverse direction that the gas supply holes 156 extend. Filler material 158 such as a paste, adhesive or other chemical-and/or plasma-resistant material may be used to fill the cavity around sides of the slanted multi-lumen plug 154.

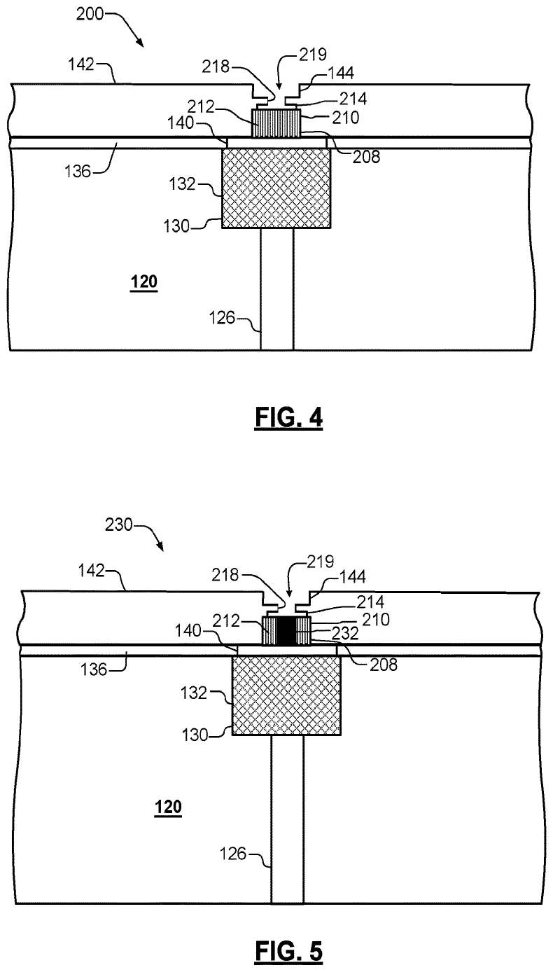

Referring now to FIG. 4, another example of an arc-resistant ESC 200 is shown. In this example, the porous plug 132 is arranged in the cavity 130 in the baseplate 120. The top ceramic layer 142 includes a cavity 208 arranged on a bottom surface of the top ceramic layer 142. The cavity 208 is vertically aligned with the vertical gas supply hole 126 and the porous plug 132.

A multi-lumen plug 210 is arranged in the cavity 208 and includes a body and a plurality of gas supply holes 212 extending parallel to one another and in a vertical direction through the body. In some examples, the bottom of the multi-lumen plug 210 and the bottom surface of the top ceramic layer 142 are coplanar. In some examples, the body of the multi-lumen plug 210 is made of ceramic (e.g., alumina). In some examples, the plurality of gas supply holes 212 include greater than or equal to 100 and less than or equal to 1000 holes. In some examples, the plurality of gas supply holes 212 have a diameter in a range from 3 μm to 10 μm.

The top ceramic layer 142 includes a plenum 214 located above the multi-lumen plug 210 (and the cavity 208). An annular projection 218 extends above the plenum 214 and defines a gas supply hole 219. The cavity 144 is located above the annular projection 218 and the gas supply hole 219. In some examples, the plenum 214 has a diameter that is smaller than a diameter of the multi-lumen plug 210. In some examples, the gas supply hole 219 is smaller than the diameter of the plenum 214.

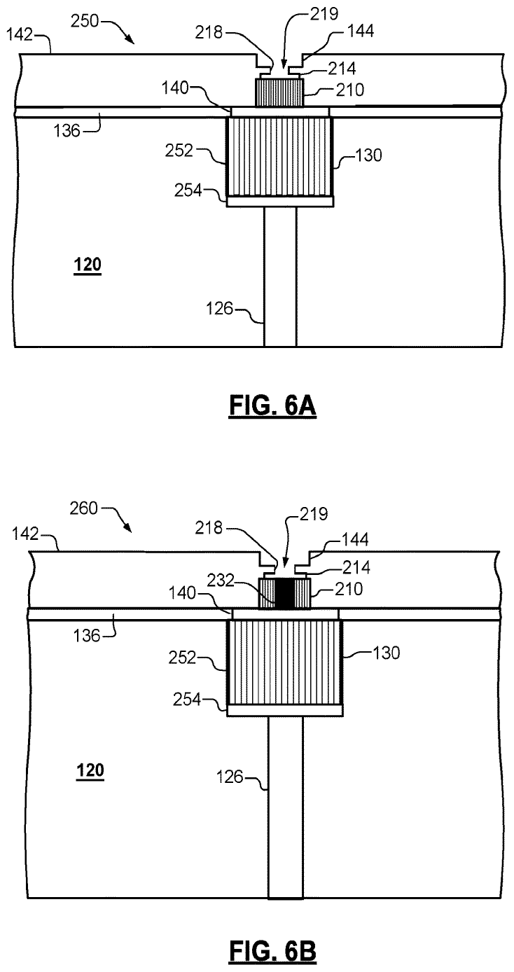

Referring now to FIG. 5, another example of an arc-resistant ESC 230 is shown that is similar to the arc-resistant ESC 200 in FIG. 4. In this example, the multi-lumen plug 210 further includes a solid core 232 (e.g., without gas supply holes) that is located concentrically relative to the multi-lumen plug 210. The gas supply holes are arranged around the solid core 232. In some examples, the solid core has a diameter in a range from 0.8 mm to 1.5 mm. In some examples, the solid core 232 has a diameter that is larger than the gas supply holes 219 and smaller than the diameter of the plenum 214. In some examples, the diameter of the gas supply hole 219 is in a range from 0.1 mm to 0.5 mm. In some examples, the diameter of the gas supply hole 219 is in a range from 0.2 mm to 0.3 mm.

Referring now to FIGS. 6A to 6D, other examples of arc-resistant ESCs are shown. In FIG. 6A, an arc-resistant ESC 250 includes the multi-lumen plug 210 arranged in the top ceramic layer 142 and a multi-lumen plug 252 arranged in the cavity 130 in the baseplate 120. In this example, the multi-lumen plug 252 includes gas supply holes 254 that are axially/vertically aligned. In some examples, a bottom surface of the multi-lumen plug 252 is spaced from a bottom surface of the cavity 130 to define a plenum 254.

In FIG. 6B, an arc-resistant ESC 260 is similar to the arc-resistant ESC 250 in FIG. 6A. However, the multi-lumen plug 210 in the cavity 208 of the top ceramic layer 142 further includes the solid core 232. In FIG. 6C, an arc-resistant ESC 270 is similar to the arc-resistant ESC 250 in FIG. 6A. However, the multi-lumen plug 210 does not include the solid core 232 and the multi-lumen plug 252 includes a solid core 274. In some examples, the solid core 274 of the multi-lumen plug 252 has a diameter that is greater than the inner diameter of the annular projection 218 and less than a diameter of the multi-lumen plug 252.

In FIG. 6D, an arc-resistant ESC 280 is similar to the arc-resistant ESC 250 in FIG. 6A. However, the multi-lumen plug 210 further includes the solid core 232 and the multi-lumen plug 252 further includes the solid core 274.

Referring now to 7, an arc-resistant ESC 300 includes the porous plug 132 arranged in the cavity 130 in the baseplate 120. The top ceramic layer 142 includes the multi-lumen plug 210 arranged in the cavity 208 on the bottom surface. Instead of the annular projection 218 being located above the plenum 214, as in FIG. 6A, the top ceramic layer 142 includes a plurality of gas supply holes 310 passing from the cavity 144 to the plenum 214.

In some examples, the plurality of gas supply holes 310 comprise 2 to 50 holes having a diameter in a range from 0.02 mm to 0.1 mm. In some examples, the plurality of gas supply holes 310 are arranged in parallel in an axial/vertical direction. In some examples, the plurality of gas supply holes 310 are made using a laser or another hole drilling device. In some examples, the plurality of gas supply holes 310 are arranged within an outer diameter that is less than or equal to a diameter of the solid core 232 arranged in the multi-lumen plug 210 located below.

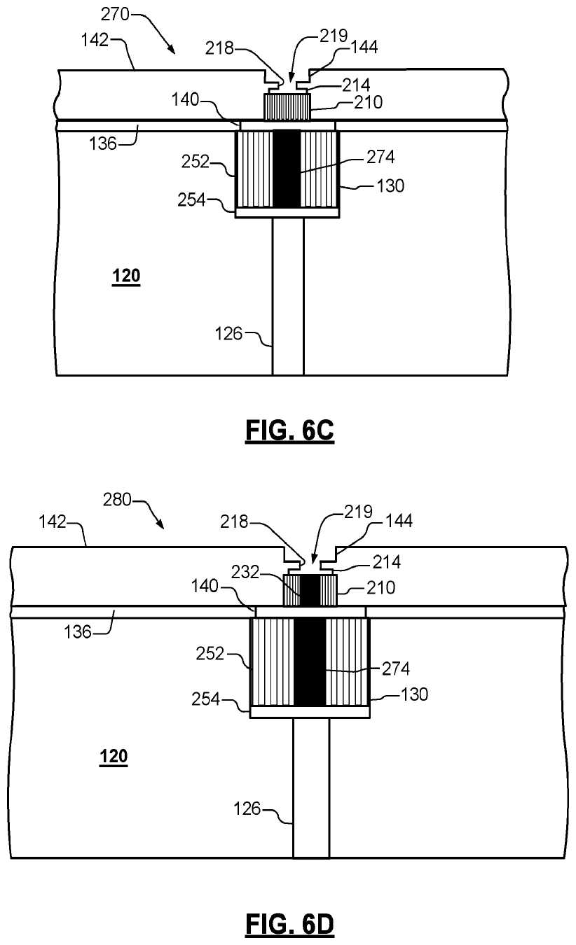

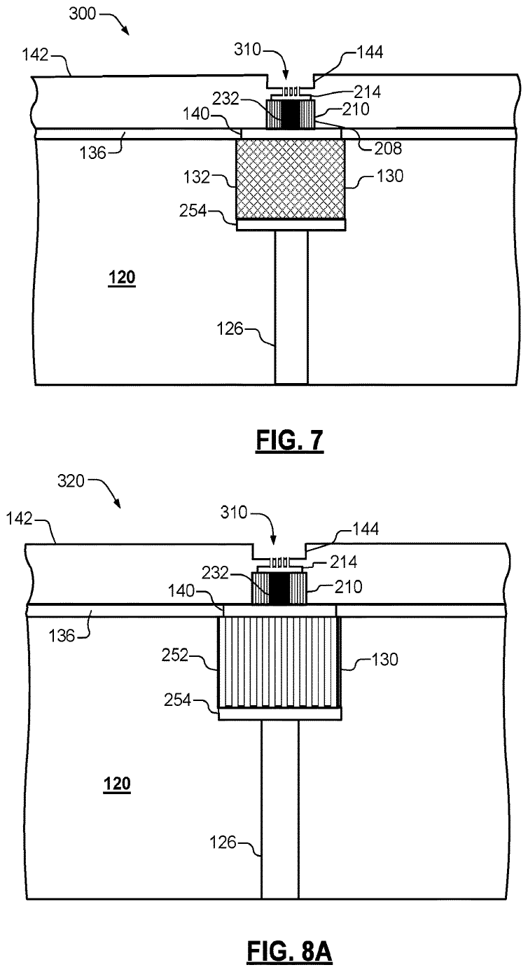

Referring now to FIGS. 8A to 8D, various examples of the arc-resistant ESC are similar to the arc-resistant ESC 300 shown in FIG. 7. In an arc-resistant ESC 320 shown in FIG. 8A, the porous plug 132 in FIG. 7 is replaced by the multi-lumen plug 252. In an arc-resistant ESC 340 shown in FIG. 8B, the porous plug 132 in FIG. 7 is replaced by the multi-lumen plug 252 with the solid core 274. In FIG. 8C, an arc-resistant ESC 350 includes the plurality of gas supply holes 310 passing from the cavity 144 to the plenum 214 as described above. The multi-lumen plug 210 is arranged in the cavity 208 and the slanted multi-lumen plug 154 is arranged in the cavity 130. As can be appreciated, the multi-lumen plug 210 may further include the solid core 232 as shown in FIG. 8D.

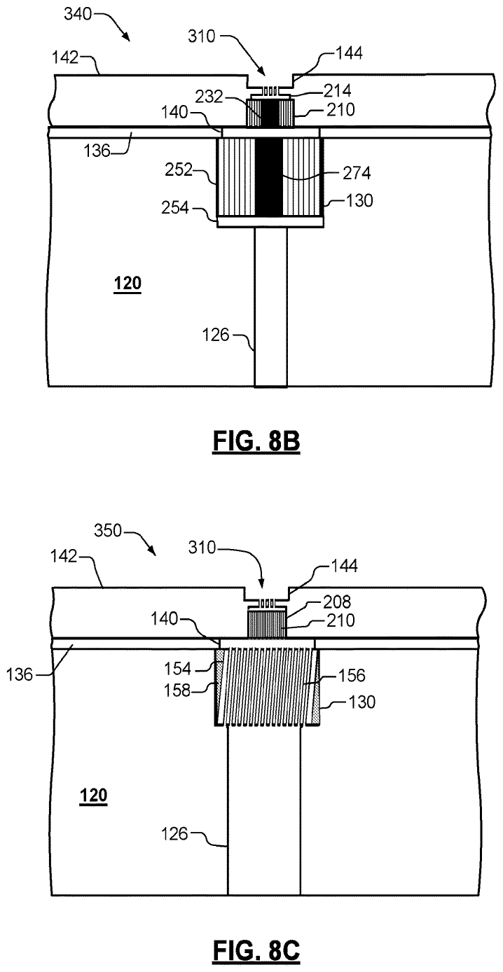

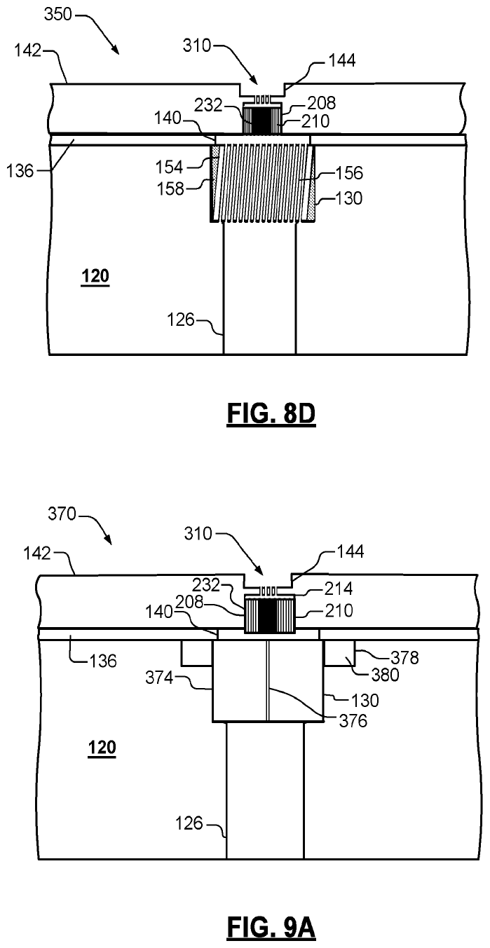

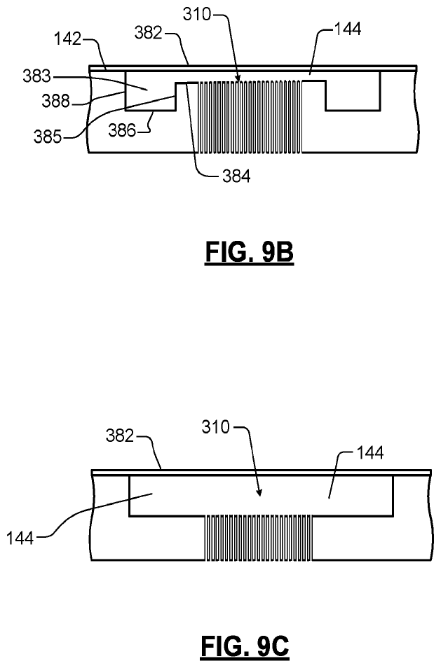

Referring now to FIGS. 9A to 9C, another arc-resistant ESC 370 is shown. The top ceramic layer 142 includes the cavity 144. In FIG. 9A, the plurality of gas supply holes 310 are arranged in the bottom surface of the cavity 144. The plenum 214 is arranged below the plurality of gas supply holes 310. The multi-lumen plug 210 with the solid core 232 is arranged in the cavity 208 of the top ceramic layer 142 and below the plenum 214.

A sleeve 374 is arranged in the cavity 130 and includes one or more gas supply holes 376 that extend vertically through the sleeve 374. In some examples, the sleeve 374 is solid and is made of ceramic. In some examples, the one or more gas supply holes 376 are located in a center of the sleeve 374 and/or below and between a radially outer edge of the solid core 232. In some examples, the one or more gas supply holes 376 have a diameter in a range from 100 μm to 500 μm.

In some examples, the cavity 130 includes an upper cavity portion 378 that extends radially outwardly near the upper surface of the baseplate 120. In some examples, the sleeve 374 has a “T”-shaped cross section and includes a flange 380 that is received in the upper cavity portion 378. The flange 380 provides improved protection since an upper corner of the upper cavity portion 378 is moved radially outwardly relative to the heat transfer gas flow.

The solid core 232 of the multi-lumen plug 210 in the top ceramic layer 142 provides sufficient shade to prevent direct line of sight into the one or more gas supply holes 376 in the sleeve 374 located below. In some examples, the multi-lumen plug 210 extends below a bottom surface of the top ceramic layer 142. In some examples, a gap below the multi-lumen plug to the top surface of the sleeve is greater than or equal to 20 μm to 100 μm and less than or equal to 0.5 mm. Minimizing the gap towards lower values in the range improves arcing and/or light-up protection. The flange 380 of the sleeve 374 can be used to provide extra protection by preventing arcing to the baseplate 120.

In FIG. 9B, a substrate 382 is shown arranged on the top ceramic layer 142. An upper surface of the top ceramic layer 142 (above the plenum 214) may include a raised portion 384 surrounded by an annular plenum 383 defined by radially inner side walls 385, a bottom surface 386, and radially outer side walls 388 in the cavity 144. In some examples shown, a vertical depth of the cavity 144 in the annular plenum 383 is in a range from 70 μm to 150 μm and a vertical depth of the cavity 144 above the raised portion 384 is in a range from 5 μm to 30 μm. Outlets of the gas supply holes 310 are located on the raised portion 384.

In FIG. 9C, the cavity 144 is disc shaped. The plurality of gas supply holes 310 are formed in the bottom surface of the cavity 144. In FIG. 9C, a vertical depth of the cavity 144 is in a range from 70 μm to 150 μm.

Referring now to FIG. 10, an arc-resistant ESC 400 includes the top ceramic layer 142 including the cavity 144. A bottom surface of the cavity 144 includes one or more gas supply holes 410 extending from the cavity 144 to the bottom surface of the top ceramic layer 142. The one or more gas supply holes 410 in the top ceramic layer 142 are arranged above the relief area 140. In some examples, the one or more gas supply holes 410 comprise 1 to 5 holes having a diameter in a range from 80 μm to 150 μm.

The multi-lumen plug 252 is arranged in the cavity 130 and includes the solid core 274. In some examples, the hole size in the multi-lumen plug 252 is in a range from 3 μm to 10 μm. In some examples, the diameter of the solid core 274 is greater than an outer diameter surrounding the one or more gas supply holes 410.

Referring now to FIG. 11, another arc-resistant ESC 420 is shown. A plug 424 includes a body defining a plenum 426 and a gas channel 428. One or more gas holes 430 connect the gas channel 428 to the plenum 426. One or more gas supply holes 432 and 434 are arranged between the plenum 426 and a top side of the plug 424. In some examples, the gas supply holes 432 and 434 are located radially outside of radially outer edges of the one or more gas supply holes 410. In some examples, the plug 424 is made of two portions 337 and 438.

In some examples, the gas supply holes 432 and 434 comprise 32 to 150 holes having a diameter in a range from 30 μm to 80 μm. In some examples, the one or more gas supply holes 410 comprise 1 to 5 holes having a diameter in a range from 50 μm to 150 μm. In some examples, the plenum 426 has a diameter in a range from 3 mm to 5 mm, a height in a range from 50 μm to 200 μm. In some examples, the one or more gas holes 430 comprise 1 to 20 holes and have a diameter in a range from 100 μm to 200 μm. In some examples, a lower portion of the sleeve 374 tapers inwardly from surfaces of the cavity 130 (e.g., by a radial distance in a range from 0.1 mm to 1mm) to increase tracking distance and prevent arcing. In some examples, the plug 424 is made of two pieces with a break line shown at 441.

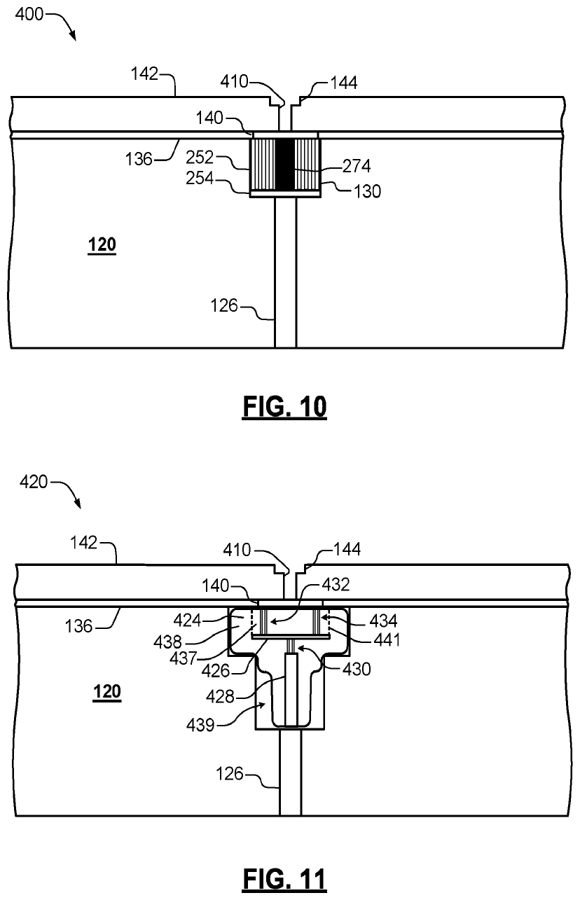

Referring now to FIGS. 12 to 14, examples of plugs that are arranged in the cavity 130 in the baseplate 120 are shown. In FIG. 12, a plug 440 has a “T”-shaped cross-section and includes a body and a flange. The plug 440 includes an annular gas channel 442 extending upwardly from a bottom surface thereof. Gas holes 446 extend from an upper surface of the plug 440 to the annular gas channel 442. In some examples, the gas holes 446 are located radially outside of radially outer edges of the one or more gas supply holes 410. In some examples, the gas holes 446 comprise 10 to 300 holes and have a diameter in a range from 30 μm to 150 μm.

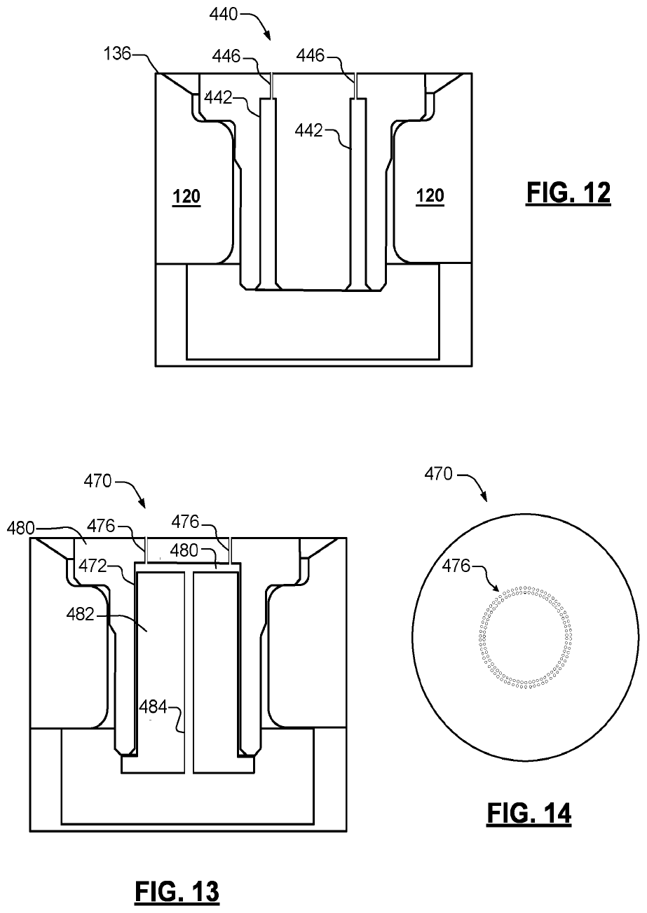

In FIG. 13, a plug 470 has a “T”-shaped outer cross-section and includes a body and a flange. The body defines a cavity 472. The plug 470 includes gas supply holes 476 extending upwardly from the cavity 472. A plug 482 has a “T”-shaped cross-section and is inserted in the cavity 472 in an inverted orientation relative to the plug 470. The plug 482 further includes a gas channel 484 that extends from a bottom surface of the plug 482 to a top surface of the plug 482. In some examples, a gap 480 is formed between the top surface of the plug 482 and a facing surface of the cavity 472.

In FIG. 14, the gas supply holes 476 are shown in the top surface of the plug 470. In some examples, one or multiple rings of gas supply holes 476 are formed in the plug 470 in a circular pattern. If multiple rings of gas supply holes 476 are used, the circular pattern of the multiple sets of gas supply holes 476 are concentric.

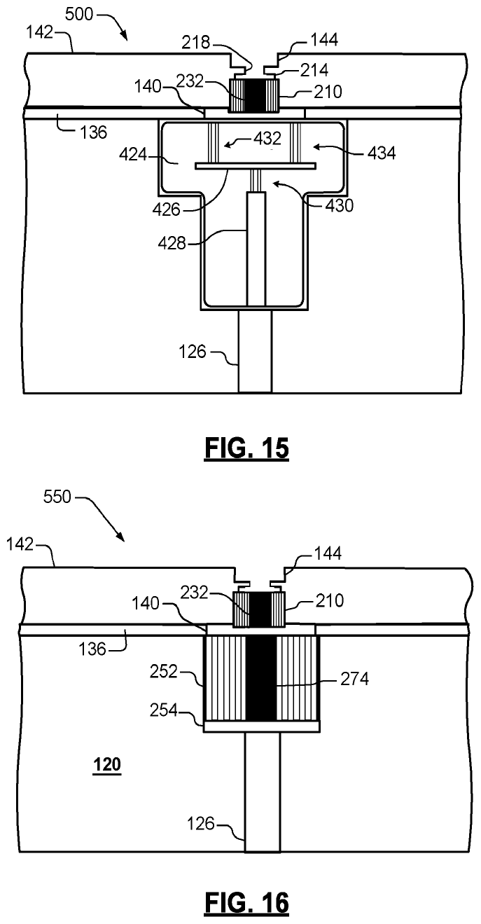

Referring now to FIG. 15, another arc-resistant ESC 500 is shown that is similar to the arc-resistant ESC 420 in FIG. 11. In FIG. 15, the multi-lumen plug 210 with the solid core 232 is arranged below the plenum 214 and above the plug 424. In some examples, a bottom surface of the multi-lumen plug 210 extends into the relief area 140 and is spaced from a top surface of the plug 424. In some examples, the multi-lumen plug 210 extends in a range from 10 μm to 150 μm into the relief area 140. In some examples, the gas supply holes 432 are arranged radially outside of an outer diameter of the multi-lumen plug 210.

Referring now to FIG. 16, another arc-resistant ESC 550 is shown that is similar to the arc-resistant ESC 500 in FIG. 11. In FIG. 16, the multi-lumen plug 210 with the solid core 232 is arranged below the plenum 214 and above the multi-lumen plug 252 with the solid core 274. In some examples, a bottom surface of the multi-lumen plug 210 extends into the relief area 140 and is spaced from a top surface of the plug 424 as described above.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.” In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1-33. (canceled)

34. An arc-resistant electrostatic chuck, comprising:
a baseplate including:
a first gas supply hole to supply a heat transfer gas; and
a first cavity arranged on a surface of the baseplate and in fluid communication with the first gas supply hole;
a top ceramic layer arranged above the baseplate and including:
a second cavity arranged on a first side of the top ceramic layer;
an annular projection extending into the first cavity and defining a gas supply hole;
a plenum arranged below the annular projection; and
a third cavity arranged below the plenum;
a bonding layer configured to bond the baseplate to the top ceramic layer and including a relief area adjacent to the first cavity;
a first plug arranged in the first cavity of the baseplate; and
a first multi-lumen plug arranged in the third cavity in the top ceramic layer and including N gas supply holes, wherein N is greater than 20.

35. The arc-resistant electrostatic chuck of claim 34, wherein N is in a range from 100 to 900.

36. The arc-resistant electrostatic chuck of claim 34, wherein the N gas supply holes have a diameter in a range from 3 μm to 10 μm.

37. The arc-resistant electrostatic chuck of claim 34, wherein the N gas supply holes are laser drilled.

38. The arc-resistant electrostatic chuck of claim 34, wherein the first plug comprises a porous plug.

39. The arc-resistant electrostatic chuck of claim 38, wherein the porous plug is in a range from 30% to 50% porous and includes open pores.

40. The arc-resistant electrostatic chuck of claim 34, wherein the first plug comprises a second multi-lumen plug including P gas supply holes, where P is an integer greater than 20.

41. The arc-resistant electrostatic chuck of claim 40, wherein the second multi-lumen plug includes a solid core and the P gas supply holes are arranged radially outside of the solid core.

42. The arc-resistant electrostatic chuck of claim 40, wherein P is an integer in a range from 100 to less than 1000 and wherein a diameter of the P gas supply holes is in a range from 3 μm to 10 μm.

43. The arc-resistant electrostatic chuck of claim 40, wherein the P gas supply holes of the second multi-lumen plug are oriented at a predetermined angle relative to a vertical direction.

44. The arc-resistant electrostatic chuck of claim 43, wherein the predetermined angle is in a range between 0.5° and 5°.

45. The arc-resistant electrostatic chuck of claim 34, wherein the first multi-lumen plug includes a solid core and wherein the N gas supply holes are located radially outside of the solid core.

46. The arc-resistant electrostatic chuck of claim 45, wherein the solid core has an outer diameter that is greater than a first diameter of the gas supply hole.

47. The arc-resistant electrostatic chuck of claim 40, wherein the first multi-lumen plug includes a solid core and wherein the second multi-lumen plug includes a solid core.

48. The arc-resistant electrostatic chuck of claim 34, wherein the first plug comprises a solid plug including a gas supply hole extending vertically through the solid plug.

49. The arc-resistant electrostatic chuck of claim 48, wherein the solid plug has a “T”-shaped cross-section and includes a flange extending outwardly from a body of the solid plug.

50. The arc-resistant electrostatic chuck of claim 34, wherein the first plug includes:
a “T”-shaped body including an annular gas channel extending from a bottom surface into the “T”-shaped body; and
gas supply holes extending from the annular gas channel to a top surface of the “T”-shaped body.

51. The arc-resistant electrostatic chuck of claim 34, wherein:
the first plug includes a first plug portion including a “T” shaped outer cross-section and a cavity extending into the first plug portion; and
a second plug portion having a “T”-shaped body that is inserted into the cavity of the first plug portion,
the second plug portion includes one or more gas supply holes extending vertically through the second plug portion, and
the first plug portion includes one or more gas supply holes extending from the cavity to a top surface of the first plug portion.

52. The arc-resistant electrostatic chuck of claim 34, wherein a bottom portion of the first multi-lumen plug extends into the relief area.

53. The arc-resistant electrostatic chuck of claim 34, wherein the first plug includes:
a body;
a plenum extending horizontally in the body;
a gas channel extending from a bottom surface of the body to a location spaced from the plenum;
P gas supply holes fluidly connecting the gas channel to the plenum; and
Q gas supply holes fluidly connecting the plenum to a top surface of the body, wherein P and Q are integers greater than one.

54. The arc-resistant electrostatic chuck of claim 53, wherein the Q gas supply holes are located radially outside of a radially outer edge of the first multi-lumen plug.

55. The arc-resistant electrostatic chuck of claim 53, wherein the Q gas supply holes comprise 32 to 150 holes having a diameter in a range from 30 μm to 80 μm.

56. The arc-resistant electrostatic chuck of claim 53, wherein the P gas supply holes comprise 1 to 20 holes having a diameter in a range from 100 μm to 200 μm.

57. The arc-resistant electrostatic chuck of claim 53, wherein a lower portion of the first plug tapers radially inwardly away from the first cavity in the baseplate.

58-82. (canceled)
